(19) United States
(12) Patent Application Publication
(10) Pub. No.: US 2016/0211353 A1
(43) Pub. Date: Jul. 21, 2016

(54) METHOD OF MANUFACTURING OXIDE THIN FILM TRANSISTOR

(71) Applicant: Samsung Display Co., Ltd., Yongin-City (KR)

(72) Inventors: Jung Yun JO, Yongin-City (KR); Su Bin BAE, Yongin-City (KR); Ki Seong SEO, Yongin-City (KR)

(21) Appl. No.: 14/966,125

(22) Filed: Dec. 11, 2015

(30) Foreign Application Priority Data
Jan. 19, 2015 (KR) 10-2015-0008842

(51) Int. Cl. H01L 29/66; H01L 29/45; H01L 29/786; H01L 29/24; H01L 21/475; H01L 21/02

(52) U.S. Cl. CPC H01L 29/66969; H01L 21/475; H01L 21/02414; H01L 21/02164; H01L 21/0217; H01L 29/7869; H01L 29/24; H01L 29/45; H01L 29/78606

(57) ABSTRACT

There is provided a method of manufacturing an oxide thin film transistor (TFT). The method includes forming a gate electrode on a substrate, forming a gale insulating layer on the gate electrode, forming an oxide semiconductor layer including a channel layer on the gate insulating layer, forming a source electrode and a drain electrode separated from each other on the oxide semiconductor layer, first plasma processing the substrate on which the source electrode and the drain electrode are formed at a carbon (C) atmosphere, secondly plasma processing the substrate al a nitrogen oxide atmosphere, and sequentially forming a first protective layer and a second protective layer on the substrate.

### CROSS-REFERENCE TO RELATED APPLICATION

This application claims priority lo and the benefit of Korean Patent Application No. 10-2015-0008842, filed on Jan. 19, 2015, in the Korean Intellectual Property Office, the entire contents of which are incorporated herein by reference in their entirety.

### BACKGROUND

1. Field

The present application relates to a method of manufacturing an oxide thin film transistor (TFT).

2. Description of the Related Art

An amorphous silicon thin film transistor (a-Si TFT) representative for display driving and m a switching device may be manufactured by a low temperature process. However, the a-Si TFT has very low mobility and does not satisfy a constant current bias condition. On the other hand, a poly-Si TFT has high mobility and a satisfactory constant current bias condition. However, it is difficult to secure a uniform characteristic. Therefore, it is difficult to enlarge an area of the poly-Si TFT and a high temperature process is returned.

Therefore, a new TFT technology having advantages (enlargement, a low price, and uniformity) of the a-Si TFT and advantages (high performance and reliability) of the poly-Si TFT is highly required and is actively studied. An oxide semiconductor is a representative one.

When the oxide semiconductor is applied to a conventional bottom gale structured TFT, the oxide semiconductor is damaged and deformed during a process of etching the source and drain electrodes.

In order to solve the problem, a method of combining oxygen (O) with a surface of the oxide semiconductor or supplying surplus O to the surface of the oxide semiconductor in a subsequent process (O plasma processing) after forming the source and drain electrodes is suggested.

### SUMMARY

An embodiment relates to a method of manufacturing an oxide thin film transistor (TFT) capable of improving a characteristic of a device and reliability of a product.

A method of manufacturing an oxide TFT according to an embodiment includes forming a gale electrode on a substrate, forming a gate insulating layer on the gate electrode, forming an oxide semiconductor layer including a channel layer on the gate insulating layer, forming a source electrode and a drain electrode separated on the oxide semiconductor layer, first plasma processing the substrate on which the source electrode and the drain electrode are formed at a carbon (C) atmosphere, secondly plasma processing the substrate at a nitrogen oxide atmosphere, and sequentially forming a first protective layer and a second protective layer on the substrate.

The oxide semiconductor layer includes one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

The first protective layer includes silicon oxide and the second protective layer includes silicon nitride.

The source electrode and the drain electrode include a copper (Cu) based conductive material formed of one or more layers.

The First plasma processing and the second plasma processing are performed in the same chamber.

A method of manufacturing an oxide thin film transistor (TFT) according to an embodiment includes forming a gale electrode on a substrate, forming a gale insulating layer on the gate electrode, forming an oxide semiconductor layer including a channel layer on the gate insulating layer, forming a source electrode and a drain electrode separated on the oxide semiconductor layer, first plasma processing the substrate on which the source electrode and the drain electrode are formed at a nitrogen oxide atmosphere, secondly plasma processing the substrate at a carbon, (C) atmosphere, and sequentially forming a first protective layer and a second protective layer on the substrate.

The oxide semiconductor layer includes one selected from the group consisting of indium-gallium-zinc oxide (IGZO) zinc oxide (ZnO), indium oxide (InO), gallium oxide (GaO), tin oxide (SnO₂), indium-gallium oxide (IGO), indium-zinc oxide (IZO). zinc-tin oxide (ZTO), and indium-zinc-tin oxide (IZTO).

The first protective layer includes silicon oxide and the second protective layer includes silicon nitride.

The source electrode and the drain electrode include a copper (Cu) based conductive material formed of one or more layers.

The first plasma processing and the second plasma processing are performed in the same chamber.

A method of manufacturing an oxide thin film transistor (TFT) according loan embodiment includes forming a gate electrode on a substrate, forming a first insulating layer on the gate electrode, forming an oxide semiconductor layer including a channel layer on the first insulating layer, forming a source electrode and a drain electrode separated on the oxide semiconductor layer, forming a second insulating layer on the source electrode and the drain electrode, plasma processing the substrate on which the second insulating layer is formed at a nitrogen oxide atmosphere, and sequentially forming a first protective layer and a second protective layer on the substrate.

The oxide semiconductor layer includes one selected from the group consisting of indium-gal Hum-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

The first protective layer includes silicon oxide and the second protective layer includes silicon nitride.

The second insulating layer includes a carbon (C) component.

A method of manufacturing an oxide thin film transistor (TFT) according to an embodiment includes forming a gale electrode on a substrate, forming a first insulating layer on the gate electrode, forming an oxide semiconductor layer including a channel layer on the first insulating layer, forming a source electrode and a drain electrode separated on the oxide semiconductor layer, plasma processing the substrate on which the source electrode and the drain electrode are formed at a nitrogen oxide atmosphere, forming a second insulating layer on the substrate, and sequentially forming a first protective layer and a second protective layer on the second insulating layer.

The oxide semiconductor, layer includes one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

The first protective layer includes silicon oxide and the second protective layer includes silicon nitride.

The second insulating layer includes a carbon (C) component.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will full convey the scope of the example embodiments to those skilled in the art.

In the drawing figures, dimensions may be exaggerated for clarity of illustration. It will be understood that when an clement is referred to as being “between” two elements, it can be the only element between the two elements, or one or more intervening elements may also be present. Like reference numerals refer to like elements throughout.

FIG. 1 is a cross-sectional view of an oxide thin film transistor (TFT) according to an embodiment;

FIG. 2 is simulation date illustrating a reaction result of copper (Cu), oxygen (O), and carbon (C);

FIGS. 3A, 3B, 3C, 3D, 3E, 3F, 3G, 3H, 3I, 3J, and 3K are cross-sectional views sequentially illustrating a method of manufacturing the oxide TFT of FIG. 1;

FIG. 4 is simulation data illustrating a reaction result of Cu, C, and Cu oxide;

FIG. 5 is a cross-sectional view of an oxide TFT according to another embodiment; and

FIGS. 6A, 6B, 6C, 6D, 6E, 6F, 6G, 6H, 6I, 6J, and 6K are cross-sectional views sequentially illustrating a method of manufacturing the oxide TFT of FIG. 5.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments arc provided so that this disclosure will be thorough and complete, and will full convey the scope of the example embodiments to those skilled in the art.

Like reference numerals refer to like elements throughout. In the drawing figures, dimensions may be exaggerated for clarity of illustration.

It will also be understood that when an clement is referred to as being “on”another element, it can be directly on the other clement, or intervening elements may also be present.

FIG. 1 is a cross-sectional view of an oxide thin film transistor (TFT) according to an embodiment.

Referring to FIG. 1, the oxide TFT according 10 the embodiment includes a substrate 100, a gate electrode 116 formed on the substrate 100, a gate insulating layer 120 formed on the gale electrode 110, an oxide semiconductor layer 130 formed on the gate insulating layer 120, a source electrode 140a and a drain electrode 140b formed on the oxide semiconductor layer 130, and a first protective layer 150 and a second protective layer 160 sequentially formed on the source electrode 140a and the drain electrode 140b.

The substrate 100 as a material for forming a device may have high mechanical strength or size stability. The material of the substrate 100 may be, for example, a glass plate, a metal plate, a ceramic plate, or plastic (polycarbonate resin, polyester resin, epoxy resin, silicon resin, or fluoride resin). However, the embodiments are not limited thereto.

A conductive layer may be a single layer formed of a metal material such as molybdenum (Mo), titanium (Ti), chrome (Cr), tantalum (Ta), tungsten (W), aluminum (Al), copper (Cu), neodymium (Nd), and scandium (Sc) or an alloy material using the above metal materials as main components or may be formed by stacking layers formed of metal materials such as Mo, Ti, Cr, Ta, W, Al, Cu, Nd, and Sc or alloy materials using the above metal materials as, main components. After forming the conductive layer on an entire surface of the substrate 100, a photolithography process is performed to form a photoresist layer pattern on the conductive layer and an unnecessary part is removed by performing etching to form the gate electrode 110.

The gate electrode 110 may have a slacked structure, for example, one selected from a double-layered structure in which a Mo layer is slacked on an Al layer, a double-layered structure in which the Mo layer is slacked on a Cu layer, a double-layered structure in which a Ti nitride layer or a Ta nitride is stacked on the Cu layer, and a double-layered structure in which the Ti nitride layer and the Mo layer are stacked.

The gate insulating layer 120 may be a single inorganic insulating layer such as a silicon (St) oxide layer, a Si oxide/nitride layer, a Si nitride/oxide layer, a Si nitride layer, and a Ta oxide layer or may be formed by stacking inorganic insulating layers such as a Si oxide layer, a Si oxide/nitride layer, a Si nitride/oxide layer, a Si nitride layer, and a Ta oxide layer.

The oxide semiconductor layer 130 may be formed of one selected from the group consisting of indium-gallium-zinc oxide (IGZO), zinc oxide (ZnO), indium oxide (InO), gallium oxide (GaO), tin oxide (SNO2), indium-gallium oxide (IGO), indium-zinc oxide (IZO), zinc-tin oxide (ZTO), and indium-zinc-tin oxide (IZTO).

The source electrode 140a and the drain electrode 140b are separated from each other by a uniform distance due to a back channel 130a on a surface of the oxide semiconductor layer 130. The source electrode 140a and the drain electrode 140b may be formed of a Cu-based metal including Cu.

The first protective layer 150 is formed on the source electrode 140a and the drain electrode 140b by plasma enhanced chemical vapor deposition (PECVD). The first protective layer 150 may be formed of Si oxide (SiOₓ) having abundant oxygen (O) and advantageous to controlling carrier concentration of the oxide semiconductor layer 130.

The second protective layer 160 is formed on the lust protective layer 150 and may be formed of Si nitride (SiNₓ) more advantageous to absorbing moisture than SiOₓ. The second protective layer 160 is formed in the same chamber as me first protective layer 150 by PECVD.

Before forming the first protective layer 150 and the second protective layer 160, in order to process the surface of the exposed oxide semiconductor layer 130, the substrate 100 on which the source electrode 140a and the drain electrode 140b are formed may be plasma processed at an O atmosphere.

At this time, since the source electrode 140a and the drain electrode 140b arc formed of the Co-based metal, the source electrode 140a and the drain electrode 140b may react to O during plasma processing so that surfaces thereof may be corroded. In order to prevent the surfaces of the source electrode 140a and the drain electrode 140b from being corroded, according to the embodiment, after the substrate 100 on which the source electrode 140a and the drain electrode 140b are formed is first plasma processed at a carbon (O atmosphere, the substrate 100 on which the source electrode 140a and the drain electrode 140b are formed is secondly plasma processed at the O atmosphere.

When the substrate 100 on which the source electrode 140a and the drain electrode 140b are formed is first plasma processed at the C atmosphere and is secondly plasma processed at the O atmosphere, O implemented into a vacuum chamber during second plasma processing reacts to C that resides on the substrate 100 so that a CO₂ gas is generated.

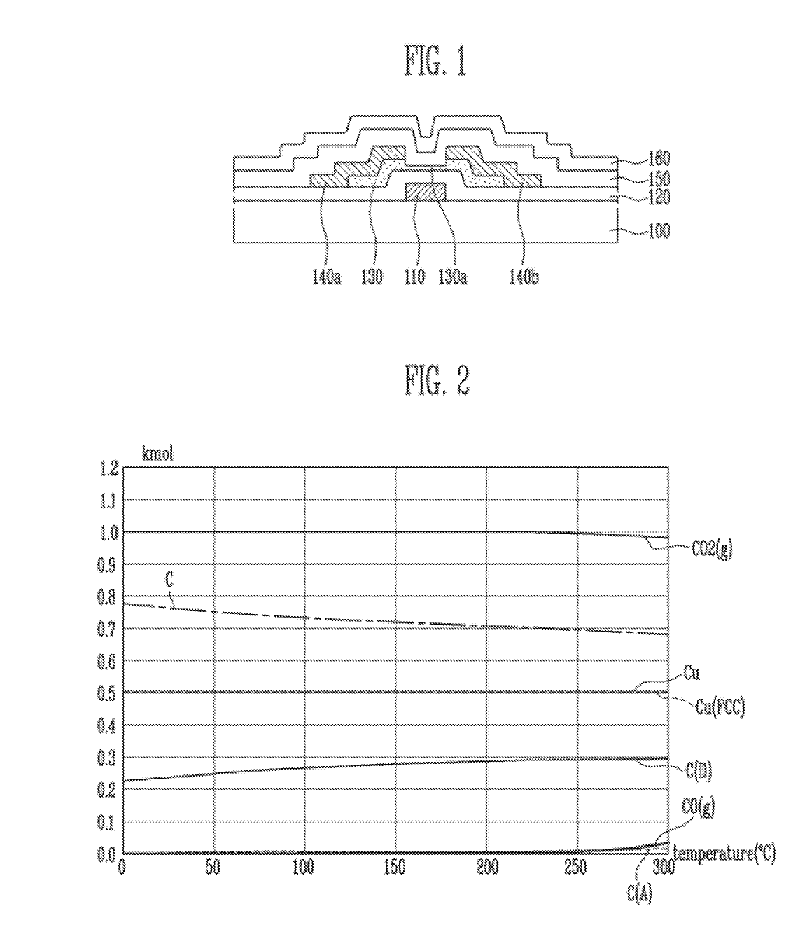

That is as illustrated in FIG. 2, O implemented into the vacuum chamber during the second plasma processing does not react to Cu of which the source and drain electrodes 140a and 140b are formed but reacts to C so that the CO₂ gas is generated.

As a result, when the substrate 100 on which the source electrode 140a and the drain electrode 140b are formed is first plasma processed at the C atmosphere and is secondly plasma processed at the O atmosphere, O reacts quicker to C than to Cu so that it is possible to prevent the surfaces of the source and drain electrodes 140a and 140b from being corroded and to improve a device characteristic of the oxide TFT.

Hereinafter, a method of manufacturing the oxide TIT having the above-described structure according to the embodiment will be described.

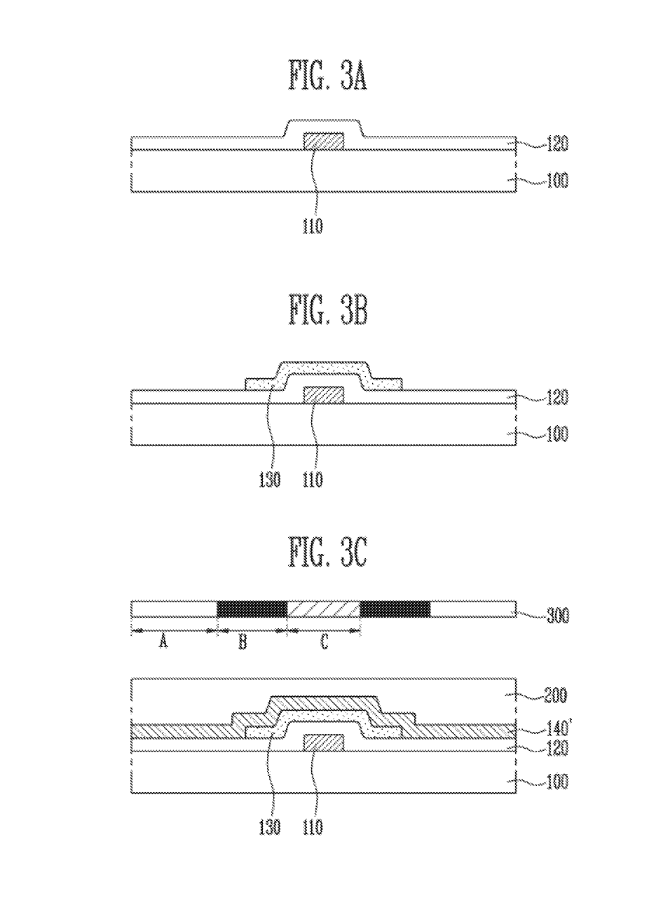

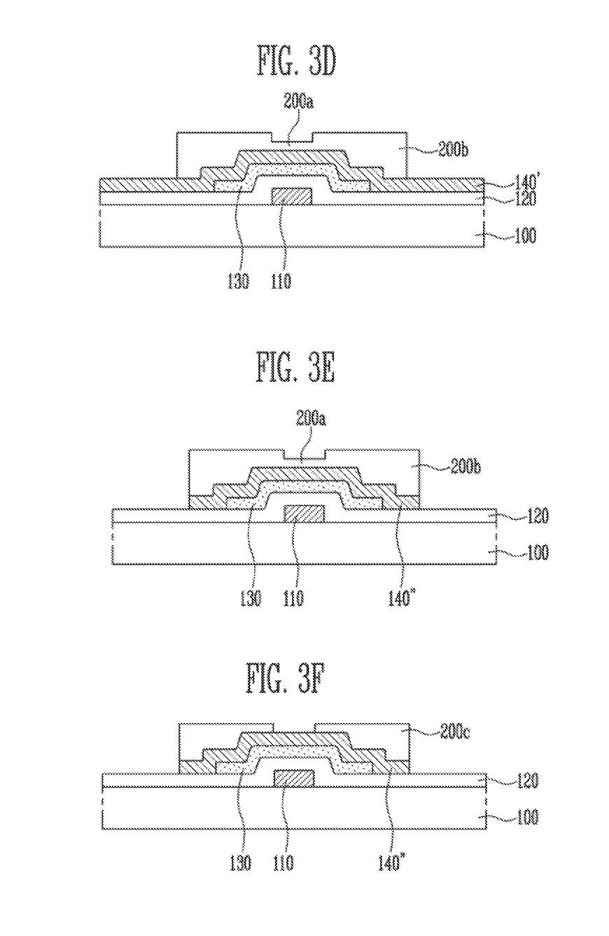

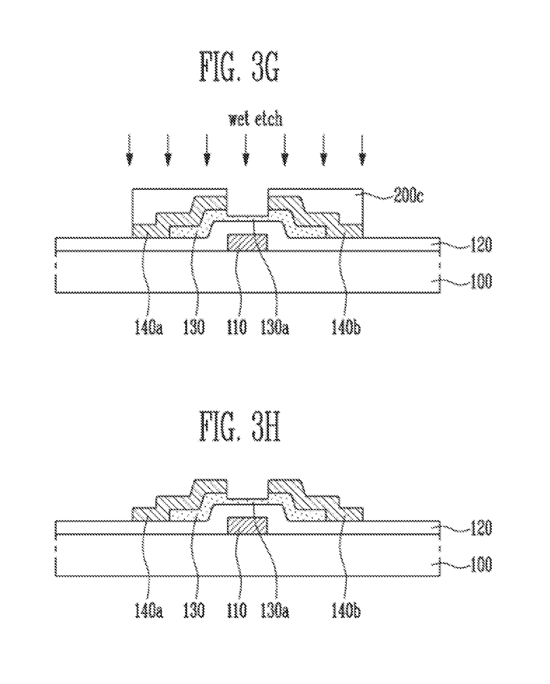

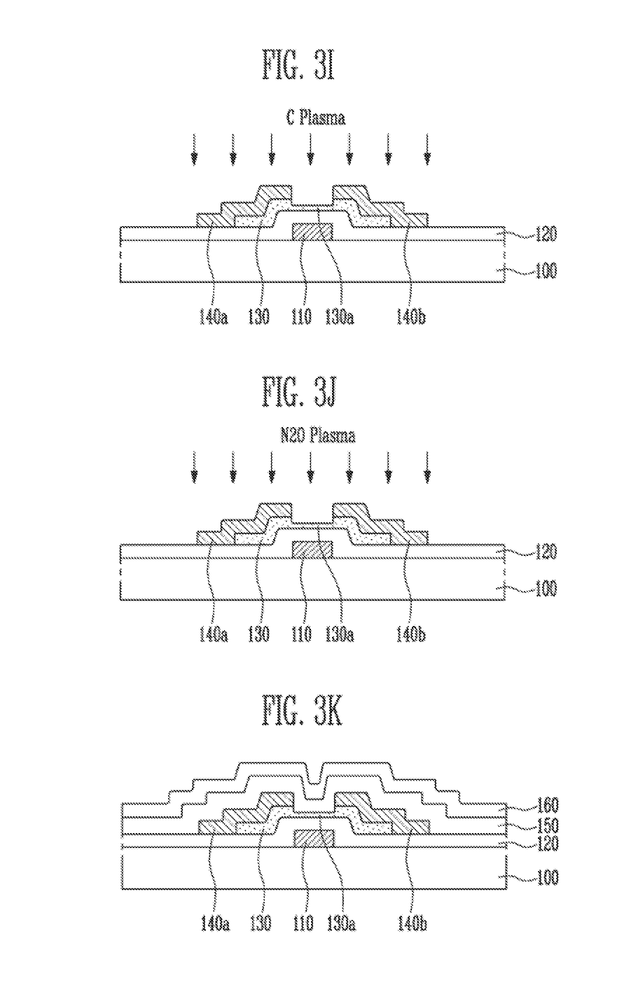

FIGS. 3A to 3K are cross-sectional views sequentially illustrating a method of manufacturing the oxide TFT of FIG. 1.

Referring to FIG. 3A, the gale electrode 110 is formed on the substrate 100 and the gate insulating layer 120 formed of SiOₓ or SiNₓ is formed on the gate electrode 110. After forming the gate insulating layer 120, wet cleaning for removing impurities that exist on a top surface of the gale insulating layer 120 may be performed.

Referring to FIG. 3B, the oxide semiconductor layer 130 corresponding to the gate electrode 110 is formed on the substrate 100 on which the gate insulating layer 120 is formed. The oxide semiconductor layer 130 may be formed of physical vapor deposition (PVD) including common sputtering and evaporation. Formation of the oxide semiconductor layer 130 by using the PVD may include at least one target selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

Referring to FIG. 3C, a conductive layer 140″ and a photoresist layer 200 are sequentially formed on the entire surface of the substrate 100 on which the oxide semiconductor layer 130 is formed. At this time, the conductive layer 140′ may he formed of a Cu-based metal material such as Cu and a Cu alloy.

After arranging a halftone mask 300 including a transmitting unit A, a blocking unit B, and a semi-transmitting unit C over the photoresist layer 200, a series of unit processes such as exposure arc performed so that a first photoresist layer pattern 200a and a second photoresist layer pattern 200b that expose a part of the conductive layer 140′ are formed as illustrated in FIG. 3D.

The first photoresist layer pattern 200a is formed to correspond to the semi-transmitting unit C of the halftone mask 300. The second photoresist layer pattern 200b is formed to correspond to the blocking unit B of the halftone mask 300 and has a thickness larger than that of the first photoresist layer pattern 200a.

Continuously, referring to FIG. 3E, the conductive layer 140′ exposed to the outside is removed by using the first photoresist layer pattern 200a and the second photoresist layer pattern 200b as etching masks so mat a conductive pattern 140″ is formed on the substrate 100.

Referring to FIG. 3F, an ashing process is performed by using O plasma lo remove the first photoresist layer pattern 200a and to expose a part of the conductive pattern 140″ to the outside. Simultaneously, a third photoresist layer pattern 200c having a smaller thickness than that of the second photoresist layer pattern 200b is formed.

Referring to FIG. 3G, a wet etching process is performed by using the third photoresist layer pattern 200e as an etching mask to remove the conductive layer 140″ exposed to the outside so that the source electrode 140a and the drain electrode 140b separated from each other by the uniform distance are formed. In addition, a part of the oxide semiconductor layer 130 is exposed to the outside.

The over-etched back channel 130a is formed on the surface of the oxide semiconductor layer 130 exposed between the source electrode 140a and the drain electrode 140b. The oxide semiconductor layer 130 is over-etched in order to completely remove a metal material from the surface of the oxide semiconductor layer 130 by using an etching solution including a material having high selectivity with respect to the oxide semiconductor layer 130.

For example, when the source electrode 140a and the drain electrode 140b are formed of Cu, a main component of the etching solution may be H₂O₂.

Continuously, the third photoresist layer pattern (200c of FIG. 3G) is removed through a strip process as illustrated in FIG. 3H.

Referring to FIG. 3I, the substrate 100 on which the source electrode 140a and the drain electrode 140b are formed is first plasma processed at the C atmosphere in order to prevent the source electrode 140a and the drain electrode 140b positioned on the uppermost layer of the substrate 100 from being combined with O implanted by a subsequent process.

Referring to FIG. 3J, the First plasma processed substrate 100 is secondly plasma processed at a N₂O atmosphere including O in order to process the surface of the back channel 130a of the oxide semiconductor layer 130 exposed lo the outside, to implement active O, and to compensate for plasma damage in a subsequent process of forming the first protective layer 150.

The first plasma processing and the second plasma processing may be performed in the same chamber since different gases may be implemented into the chamber.

During live second plasma processing, although O is implemented into the chamber, O is quicker combined with C that resides in the chamber and/or on the substrate 100 than with Cu so that the CO₂ gas is generated.

That is, since O implanted into the chamber during the second plasma processing first reacts to C, it is possible to prevent the surfaces of the source electrode 140a and the drain electrode 140b from being corroded.

At this time, an order of the first plasma processing and the second plasma processing may change. Specifically, the N₂O gas including O is first implemented into the vacuum chamber to first plasma process the substrate 100 and, continuously, a gas including C is implemented into the vacuum chamber to secondly plasma process the substrate 100.

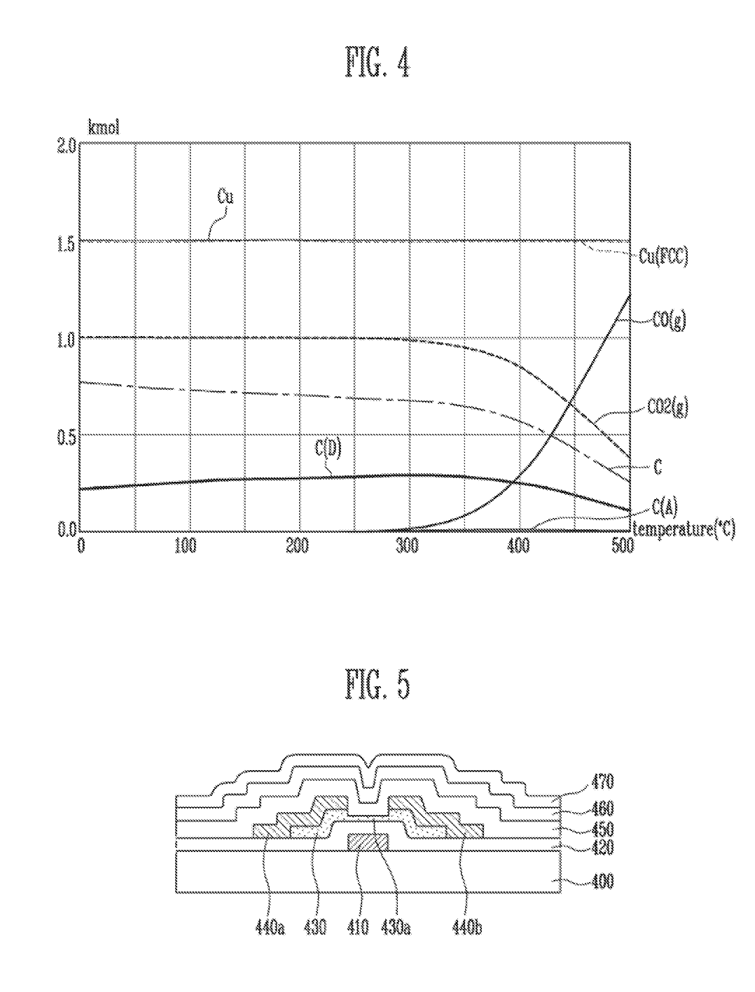

O implanted into the vacuum chamber during the first plasma processing first reacts to Cu of the source electrode 140a and the drain electrode 140b so that Cu oxide (CuOₓ) may be generated. However, since continuously implemented C reacts lo CuOₓ as illustrated in FIG. 4 to reduce CuOₓ, CuOₓ may be removed. Therefore, it is possible to prevent the surfaces of the source electrode 140a and the drain electrode 140b of the substrate 100 from being corroded.

As a result, it is possible to prevent the surface of the source electrode 140a and the surface of the drain electrode 140b from being corroded and to improve the device characteristic of the oxide TFT.

Referring to FIG. 3K, the first protective layer 150 and the second protective layer 560 are sequentially formed on the substrate 100 on which the first plasma processing process and the second plasma processing process arc performed. The first protective layer 150 is formed on the source electrode 140a and the drain electrode 140b by the PECVD. The first protective layer 150 may be formed of SiOₓ having abundant O and advantageous to controlling carrier concentration of the oxide semiconductor layer 130.

The second protective layer 160 is formed on the first protective layer 150 and may be formed of SiNₓ more advantageous to absorbing moisture than SiOₓ. The second protective layer 160 is formed in the same chamber as the first protective layer 150 by the PECVD.

FIG. 5 is a cross-sectional view of an oxide TFT according to another embodiment. Description of the same elements us those of the above-described embodiment will not be given and description will be given based on differences.

Referring to FIG. 5, the oxide TFT according to another embodiment includes a substrate 400. a gate electrode 410 formed on the substrate 400, a first insulating layer 420 formed on the gate electrode 410, an oxide semiconductor layer 410 formed on the first insulating layer 420, a source electrode 440a and a drain electrode 440b formed on the oxide semiconductor layer 430, a second insulating layer 450 formed on the source electrode 440a and the drain electrode 440b, and a first protective layer 460 and a second protective layer 470 sequentially formed on the second insulating layer 450.

The first insulating layer 420 prevents impurities from the substrate 400 from permeating into the oxide semiconductor layer 430 by using an inorganic insulating layer such as a Si oxide layer, a Si oxide/nitride layer, a Si nitride/oxide layer, a Si nitride layer, and a Ta oxide layer.

The oxide semiconductor layer 430 may be formed of one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

The source electrode 440a and the drain electrode 440b arc separated from each other by a uniform distance due to a back channel 430a of the oxide semiconductor layer 430. The source electrode 440a and the drain electrode 440b may be formed of a Cu-based metal including Co.

The second insulating layer 450 as an insulating layer including C surrounds the source electrode 440a and the drain electrode 440b that are exposed to the outside on the substrate 400. When O is implanted in order to process the surface of the back channel 430a of the oxide semiconductor layer 430, the second insulating layer 450 makes O react quicker to C than to Cu to prevent the source electrode 440a and the drain electrode 440b from being corroded.

As a result, it is possible to prevent the surfaces of the source electrode 440a and the drain electrode 440b from being corroded and to improve a device characteristic of the oxide TFT.

The first protective layer 460 is formed on the second insulating layer 450 by the PECVD, The first protective layer 460 may be formed of SiOₓ having abundant O and advantageous to controlling carrier concentration of the oxide semiconductor layer 430.

Although the first protective layer 460 formed of SiOₓ is formed on the source electrode 440a and the drain electrode 440b, the second insulating layer 450 is directly arranged under the first protective layer 460 so that O reacts quicker to C than to Cu and it is possible to prevent the source electrode 440a and the drain electrode 440b from directly contacting O.

The second protective layer 470 is formed on the first protective layer 460 and may be formed of SiNₓ more advantageous to absorbing moisture than SiOₓ. The second protective layer 470 is formed in the same chamber as the first protective layer 460 by the PECVD.

As described above, since it is possible to prevent the source electrode 440a and the drain electrode 440b from directly contacting O by the second insulating layer 450 including C, it is possible to prevent the source electrode 440a and Ute drain electrode 440b from being corroded. Therefore, it is possible to improve the device characteristic of the oxide TFT.

Hereinafter, a method of manufacturing the oxide TFT having the above-described structure according to another embodiment will be described.

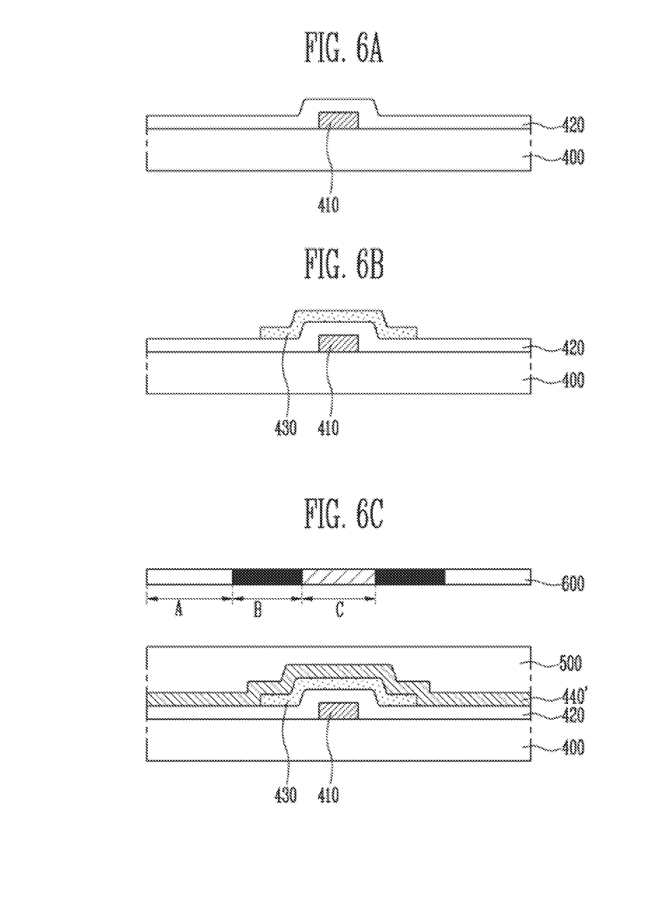

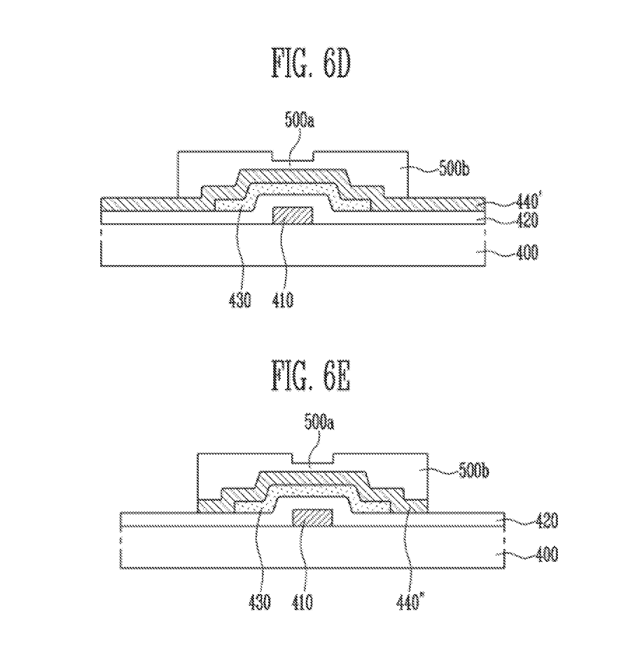

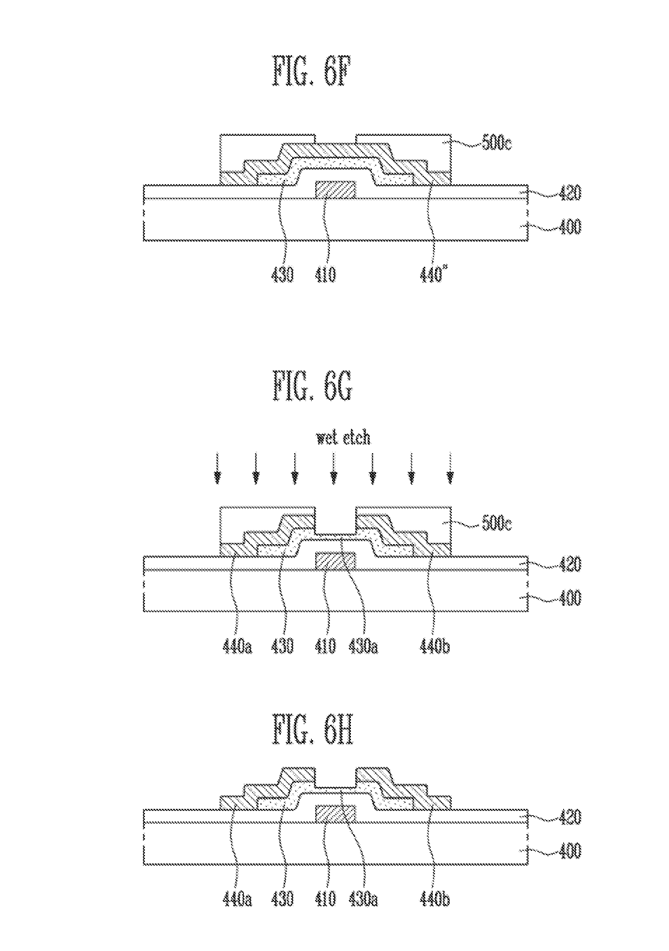

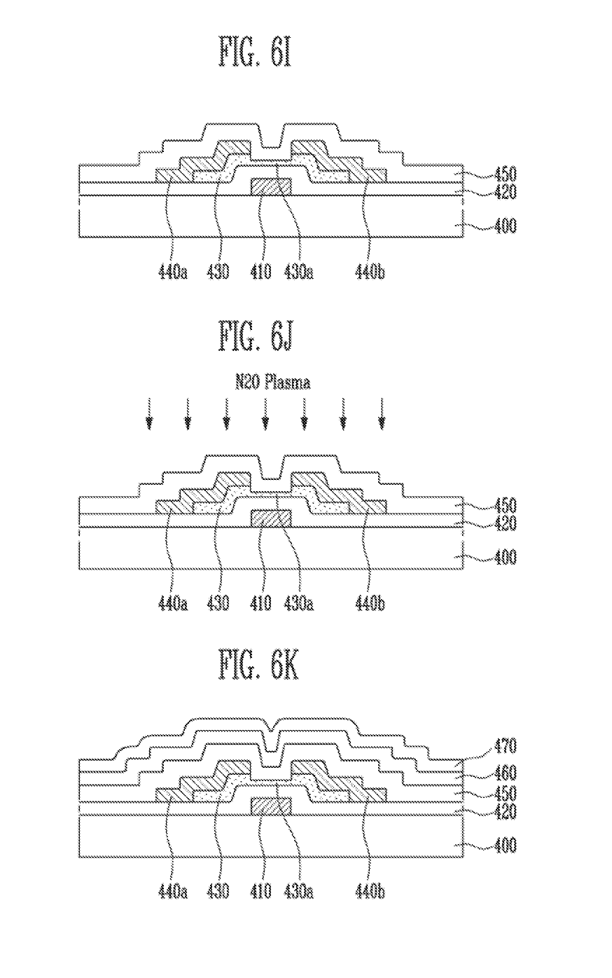

FIGS. 6A to 6K arc cross-sectional views sequentially illustrating a method of manufacturing the oxide TFT of FIG. 5.

Referring to FIG. 6A, the gale electrode 410 is formed on the substrate 400 and the first insulating layer 420 formed of SiOₓ or SiNₓ is formed on the gate electrode 410. After forming the first insulating layer 430, wet cleaning for removing impurities that exist on a top surface of the first insulating layer 420 may be performed.

Referring to FIG. 6B, the oxide semiconductor layer 430 corresponding lo the gale electrode 410 is formed on the substrate 400 on which the first insulating layer 420 is formed. The oxide semiconductor layer 430 may be formed of the PVD including common sputtering and evaporation. Formation of the oxide semiconductor layer 430 by using the PVD may include at least one target selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

Referring to FIG. 6C, a conductive layer 440′ and a photoresist layer 500 arc sequentially formed on the entire surface of the substrate 400 on which the oxide semiconductor layer 430 is formed. At this time, the conductive layer 440′ may be formed of a Cu-based metal material such as Cu and a Cu allay.

After arranging a halftone mask 600 including a transmitting unit A, a blocking unit B. and a semi-transmitting unit O over the photoresist layer 500, a series of unit processes such as exposure are performed so that a first photoresist layer pattern 500a and a second photoresist layer pattern 500b (hat expose a part of the conductive layer 440′ are formed as illustrated in FIG. 6D.

The first photoresist layer pattern 500a is formed to correspond to the semi-transmitting unit C of the halftone mask 600. The second photoresist layer pattern 500b is formed to correspond to the blocking unit B of the halftone mask 600 and has a thickness larger than that of the first photoresist layer pattern 500a.

Continuously, referring to FIG. 6E, the conductive layer 440′ exposed to the outside is removed by using the first photoresist layer pattern 500a and the second photoresist layer pattern 500b as etching masks so that a conductive pattern 440″ is formed on the substrate 400.

Referring to HO. 6F. an ashing process is performed by using O plasma to remove the first photoresist layer pattern 500a and to expose a part of the conductive pattern 440″ to the outside. Simultaneously, a third photoresist layer pattern 500c having a smaller thickness man that of the second photoresist layer pattern 500b is formed.

Referring w FIG. 6C, a wet etching process is performed by using the third photoresist layer pattern 500c as an etching mask to remove the conductive layer 440″ exposed to the outside so that the source electrode 440a and the drain electrode 440b separated from each other by the uniform distance are formed. In addition, a part of the oxide semiconductor layer 430 is exposed to the outside.

The over-etched back channel 430a is formed on the surface of the oxide semiconductor layer 430 exposed between the source electrode 440a and the drain electrode 440b. The back channel 430a for completely removing a metal material from the surface of the oxide semiconductor layer 430 is formed by using an etching solution including a material having high selectivity with respect to the oxide semiconductor layer 430.

Continuously, the third photoresist layer pattern (500c of FIG. 6G) is removed through a strip process as illustrated in FIG. 6H.

Referring to FIG. 6I, the second insulating layer 450 including C is formed on the entire surface of the substrate 400 on which the source electrode 440a and the drain electrode 440b are formed in order to prevent the source electrode 440a and the drain electrode 440b from contacting O generated by a subsequent process.

Referring to FIG. 6J, the substrate 400 on which the second insulating layer 450 is formed is plasma processed at a N₂O atmosphere including O in order to process the surface of the back channel 430a of the oxide semiconductor layer 430 exposed to the outside, to implement active O, and to compensate for plasma damage in a subsequent process of forming the first protective layer 460.

The formation of the second insulating layer 450 on the substrate 400 and the plasma processing may be performed in the same chamber.

At this lime, the second insulating layer 450 may be formed on the substrate 400 after plasma processing the substrate 400 on which the source electrode 440a and the drain electrode 440b are formed.

Specifically, the substrate 400 on which the source electrode 440a and the drain electrode 440b are formed is plasma processed at the N₂O atmosphere including O and the second insulating layer 450 including C is formed on the entire surface of the substrate 400 plasma processed.

During plasma processing, O implemented into the chamber may first react to Cu to generate CuOₓ. However, since the second insulating layer 450 including C is formed on the substrate 400 in a subsequent process, C may react to CuOₓ to reduce CuOₓ and to remove CuOₓ. Therefore, it is possible to prevent the surfaces of the source electrode 440a and the drain electrode 440b of the substrate 400 from being corroded.

As a result, it is possible to prevent the surfaces of the source electrode 440a and the drain electrode 440b from being corroded and to improve the device characteristic of the oxide TFT.

Referring to FIG. 6K, the first protective layer 460 and the second protective layer 470 arc sequentially formed on the plasma processed substrate 400. The first protective layer 460 is formed on the second insulating layer 450 by the PECVD. The first protective layer 460 may be formed of SiOₓ having abundant O and advantageous to controlling carrier concentration of the oxide semiconductor layer 430.

The second protective layer 470 is formed on the first protective layer 460 and may be formed of SiNₓ more advantageous to absorbing moisture than SiOₓ. The second protective layer 470 is formed in the same chamber as the first protective layer 460 by the PECVD.

By way of summation and review, the source electrode and the drain electrode arc formed of a Cu metal having a high non-resistivity characteristic and a high electron mobility characteristic. When the O plasma processing is performed after forming the source electrode and the drain electrode, O and Cu react to each other so that the surface of the source electrode and the surface of the drain electrode may be corroded. Therefore, the device characteristic of the TFT including oxide semiconductor may deteriorate.

In addition, the protective layer formed of SiOₓ for implanting active O into the oxide semiconductor is positioned on the source electrode and the drain electrode. In a part in which the protective layer and the source and drain electrodes contact, an O component of the protective layer and Cu of the source and drain electrodes react to each other so that the surfaces of the source electrode and the drain electrode may be corroded. Therefore, the device characteristic of the TFT including the oxide semiconductor may deteriorate.

In the method of manufacturing the oxide TFT according to the embodiment, after forming the source electrode and the drain electrode, plasma processing including C is performed or the insulating layer including C is formed so that it is possible to prevent the source electrode and the drain electrode from directly contacting O.

In addition, in the method of manufacturing the oxide TFT according to the embodiment, it is possible to prevent the source electrode and the drain electrode from directly contacting O and to improve the device characteristic of the oxide TFT.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the inventive concept as set forth in the following claims.

What is claimed is:

1. A method of manufacturing an oxide thin film transistor (TFT), the method comprising:
forming a gate electrode on a substrate;
forming a gate insulating layer on the gate electrode;
forming an oxide semiconductor layer including a channel layer on the gate insulating layer;
forming a source electrode and a drain electrode separated from each other on the oxide semiconductor layer;
first plasma processing the substrate on which the source electrode and the drain electrode are formed at a carbon (C) atmosphere;
secondly plasma processing the substrate at a nitrogen oxide atmosphere: and
sequentially forming a first protective layer and a second protective layer on the substrate.

2. The method claim 1, wherein the oxide semiconductor layer includes one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

3. The method of claim 1, wherein the first protective layer comprises silicon oxide and the second protective layer comprises silicon nitride.

4. The method of claim 1, wherein the source electrode and the drain electrode comprise a copper (Cu) based conductive material formed of one or more layers.

5. The method of claim 1, wherein the first plasma processing and the second plasma processing are performed in the same chamber.

6. A method of manufacturing an oxide thin film transistor (TFT), the method comprising:
forming a gale electrode on a substrate;
forming a gate insulating layer on the gate electrode;
forming an oxide semiconductor layer including a channel layer on the gate insulating layer;
forming a source electrode and a drain electrode separated from each other on the oxide semiconductor layer;
first plasma processing the substrate on which the source electrode and the dram electrode are formed at a nitrogen oxide atmosphere;
secondly plasma processing the substrate at a carbon (C) atmosphere; and
sequentially forming a first protective layer and a second protective layer on the substrate.

7. The method of claim 6, wherein the oxide semiconductor layer is formed of one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

8. The method of claim 6, wherein the first protective layer comprises silicon oxide and the second protective layer comprises silicon nitride.

9. The method of claim 6, wherein the source electrode and the dram electrode comprise a copper (Cu) based conductive material formed of one or more layers.

10. The method of claim 6, wherein the first plasma processing and the second plasma processing are performed in the same chamber.

11. A method of manufacturing an oxide thin film transistor (TFT), the method comprising:
forming a gate electrode on a substrate;
forming a first insulating layer on the gate electrode;
forming an oxide semiconductor layer including a channel layer on the first insulating layer;
forming a source electrode and a drain electrode separated from each other on the oxide semiconductor layer;
forming a second insulating layer on the source electrode and the drain electrode; and
sequentially forming a first protective layer and a second protective layer on the substrate.

12. The method of claim 11, further comprising plasma processing the substrate on which the second insulating layer is formed at a nitrogen oxide atmosphere.

13. The method of claim 11, further comprising plasma processing the substrate on which the source electrode and the drain electrode are formed at a nitrogen oxide atmosphere.

14. The method of claim 11, wherein the oxide semiconductor layer includes one selected from the group consisting of indium-gallium-zinc oxide (IGZO), zinc oxide (ZnO), indium oxide (InO), gallium oxide (GaO), tin oxide (SnO₂), indium-gallium oxide (IGO), indium-zinc oxide (IZO), zinc-tin oxide (ZTO), and indium-zinc-tin oxide (IZTO).

15. The method of claim 11, wherein the first protective layer comprises silicon oxide and the second protective layer comprises silicon nitride.

16. The method of claim 11, wherein the second insulating layer comprises a carbon (C) component.
